(19) United States
(12) Patent Application Publication
(10) Pub. No.: US 2026/0068611 A1
(43) Pub. Date: Mar. 5, 2026

(54) BOND SHIFT DETECTION FOR BONDED SUBSTRATES

(71) Applicant: Taiwan Semiconductor Manufacturing Company, Ltd., Hsinchu (TW)

(72) Inventors: Wei-Yu Chou, Hsinchu (TW); Yang-Che Chen, Hsin-Chu City (TW); Yi-Lun Yang, Taoyuan City (TW); Ting-Yuan Huang, Yilan County (TW); Hsiang-Tai Lu, Zhubei City (TW); Wei-Ray Lin, Hsinchu City (TW)

(21) Appl. No.: 18/819,239

(22) Filed: Aug. 29, 2024

(51) Int. Cl. H01L 23/00; H01L 21/66; H01L 25/065

(52) U.S. Cl. CPC H01L 22/32

(57) ABSTRACT

Some embodiments relate to an integrated device, including: a first interconnect structure on a first substrate; a first central bond pad coupled to the first interconnect structure; a first peripheral bond pad on a first side of the first central bond pad separated by a first distance; a second peripheral bond pad on a second side of the first central bond pad and separated by a second distance substantially equal to the first distance; a second interconnect structure on a second substrate; a first overlying bond pad coupled to the second interconnect structure and bonded to the first central bond pad; and a plurality of exposed bond pads respectively coupled to the first central bond pad, the first peripheral bond pad, the second peripheral bond pad, and the first overlying bond pad, wherein the plurality of exposed bond pads extend past outer sidewalls of the second substrate.

### BACKGROUND

Integrated circuits (ICs) comprise a plurality of integrated circuit components coupled together by an interconnect structure. The amount of circuit components and the size of the interconnect structure is limited by the thermal and space requirements of the circuit components. The amount of circuit components used and the size of the resulting circuit may be increased by bonding separate substrates together. Methods of bonding the substrates together include metal-to-metal bonding, dielectric-to-dielectric bonding, and micro bump bonding.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C illustrate a cross-sectional view, a top view, and a three dimensional view of some embodiments of a bonding test structure to detect an offset in the placement of an overlying substrate.

FIGS. 2A and 2B illustrate cross-sectional views of some embodiments of a method of detecting an offset in the placement of the overlying substrate.

FIGS. 3A-3D illustrate top views of one or more bonding test structures for determining the degree of offset in the placement of the overlying substrate and a rotation in the placement of the overlying substrate.

FIGS. 4A, 4B, and 4C illustrate a top view and cross-sectional views comparing some embodiments of an overlying substrate with no offset in the placement of the overlying substrate and an overlying substrate with a detectable offset in the placement of the overlying substrate.

FIGS. 5A, 5B, and 5C illustrate a top view and three dimensional views of some embodiments of an overlying substrate with a detectable degree of rotation, a first bonding test structure at a first corner of the overlying substrate, and a second bonding test structure at a second corner of the overlying substrate.

FIG. 6 illustrates a cross-sectional view of a bonding test structure where the overlying substrate is coupled to the underlying wafer using a plurality of micro-bumps.

FIGS. 7A, 7B, and 7C illustrate a cross-sectional view and top views of device region surrounded by a seal ring where the test structure is positioned in a dummy metal region.

FIGS. 8-13 illustrate a series of cross-sectional views of some embodiments of a method of forming the bonding test structure and testing for an offset in the placement of the overlying substrate.

FIG. 14 illustrates a flowchart of some embodiments of a method of forming the bonding test structure and testing for an offset in the placement of the overlying substrate.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

An integrated circuit comprises a plurality of circuit components coupled together by an interconnect structure. The interconnect structure forms a plurality of conductive paths between the circuit components, electrically coupling the circuit components together to form the integrated circuit. Integrated circuits are used to form a variety of products such as, for example, computers, memory banks, image sensors, and the like. In order to form more complicated circuits and to connect subcircuits formed on different substrates together, wafers and dies are bonded together at bonding interfaces, where a first interconnect structure on a first substrate is coupled to a second interconnect structure on a second substrate. The bonding may be through a metal-to-metal bond and/or a dielectric-to-dielectric bond, a micro-bump bond, or another bonding method. The bonding may be a die-to-die bond, a wafer-to-wafer bond, a die-to-wafer bond, or the like.

When the first interconnect structure is bonded to the second interconnect structure, specific conductive paths of the first interconnect structure are coupled to specific conductive paths of the second interconnect structure to integrated circuits on the first substrate and circuits on the second substrate. In some embodiments, the first interconnect structure is placed on the second interconnect structure using a pick-and-place process. However, the small size of the first substrate and the second substrate in combination with errors or inaccuracies in the pick-and-place process may result in errors in the placement of the second substrate on the first substrate. These errors may be a translation of the second substrate across the first substrate in one or more directions, or a rotation of the second substrate compared to its intended position. The errors may result in a misalignment of the conductive paths, resulting in an increased resistance, poor bond strength, or potentially a mismatch or wholly missed connection, resulting in failure of the integrated circuit and yield issues in the production of the device. Optical inspection may be used to catch errors in the alignment of the second substrate over the first substrate. However, optical inspection is time intensive, uses additional tools, and its effectiveness is dependent on the surface quality and design of the alignment marks on the first and second substrate. Therefore, a method of detecting an offset in the placement of an overlying substrate that is independent of the surface quality of the first and second substrate is desirable.

The present disclosure provides for bonding test structure at a bond interface. A first central bond pad and a first plurality of peripheral bond pads surround the first central bond pad in a first bonding layer on the first interconnect structure. A first overlying bond pad is in a second bonding layer on a second interconnect structure coupled to the overlying substrate. After the first bonding layer is bonded to the second bonding layer, an electrical test is performed. A first exposed bond pad is coupled to the first overlying bond pad by a conductive path extending through the second interconnect structure and the first interconnect structure. A test voltage is applied to the first exposed bond pad. A plurality of output voltages are measured at exposed bond pads coupled to the first central bond pad and the first plurality of peripheral bond pads. A voltage measurement higher than a threshold voltage (e.g., greater than 0.1 volts) measured at an exposed bond pad coupled to one of the bond pads of the first plurality of peripheral bond pads indicates a shift in the overlying bond pad (and therefore the second substrate) in the direction of the bond pad from the first central bond pad.

Additional bonding test structures with varying distances between the central bond pads and the peripheral bond pads may be formed to determine the degree of offset of the second substrate from its expected position. Additional bonding test structures at opposing corners of the second interconnect structure on the second substrate may be formed to determine a magnitude and direction of a rotation of the second substrate from its expected position.

Determining the direction and rotation of offset of an overlying substrate is useful for determining the success of the bonding process and making corrections to the pick-and-place process, resulting in increased production yields.

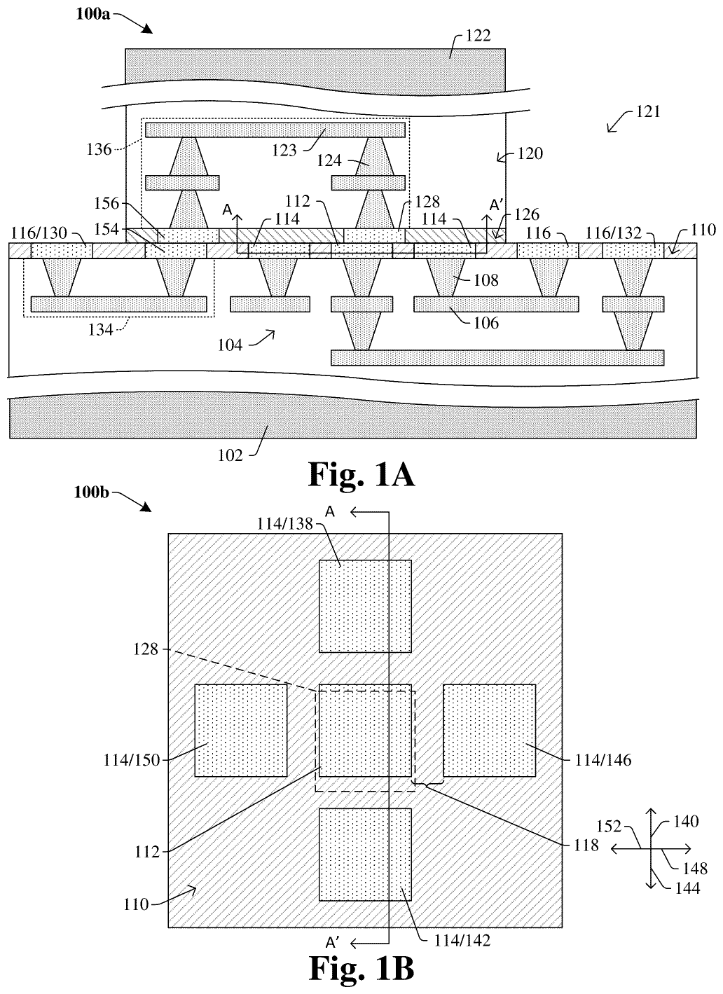

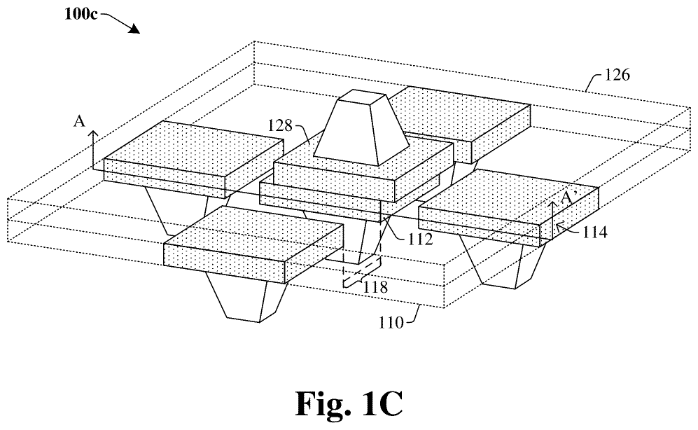

FIGS. 1A, 1B, and 1C illustrate a cross-sectional view 100a, a top view 100b, and a three dimensional view 100c of some embodiments of a bonding test structure to detect an offset in the placement of an overlying substrate. The cross-sectional view 100a of FIG. 1A is taken across line A-A′ of the top view of FIGS. 1B and 1C.

As shown in the cross-sectional view 100a of FIG. 1A, a first interconnect structure 104 is on a first substrate 102. The first substrate 102 is part of a first wafer or first die. The first interconnect structure 104 comprises a first plurality of wire levels 106 and a first plurality of via levels 108 arranged to form conductive paths. A first bonding layer 110 is on the first interconnect structure 104. The first bonding layer 110 comprises a first central bond pad 112, a first plurality of peripheral bond pads 114, and a first plurality of exposed bond pads 116. The first plurality of peripheral bond pads 114 surround the first central bond pad 112 and are a first distance 118 away from the first central bond pad 112.

A second interconnect structure 120 is on a second substrate 122 over the first substrate 102. The second substrate 122 is part of a second wafer or second die. The second substrate 122 is also referred to as an overlying substrate. The second interconnect structure 120 comprises a second plurality of wire levels 123 and a second plurality of via levels 124 arranged to form conductive paths. A second bonding layer 126 is on the second interconnect structure 120. The second bonding layer 126 comprises a first overlying bond pad 128 directly over the first central bond pad 112. The first overlying bond pad 128 is bonded to the first central bond pad 112 at a first bond interface, electrically coupling the first interconnect structure 104 to the second interconnect structure 120. In some embodiments, the first central bond pad 112 is bonded to the first overlying bond pad 128 in a metal-to-metal bond. The first plurality of exposed bond pads 116 are arranged past outer sidewalls of the second substrate 122 and the second interconnect structure 120. In some embodiments, the first plurality of exposed bond pads 116 are 5 to 10 times larger than the first central bond pad. The increased size improves the accuracy of probe testing performed on the integrated device.

Conductive paths in the first interconnect structure 104 are coupled to the first plurality of exposed bond pads 116, the first central bond pad 112, and the first plurality of peripheral bond pads 114. The first plurality of exposed bond pads 116 are respectively coupled to bond pads of the first plurality of peripheral bond pads 114. A first exposed bond pad 130 of the first plurality of exposed bond pads 116 is coupled to the first overlying bond pad 128 by a combination of a first conductive path 134 in the first interconnect structure 104 and a second conductive path 136 in the second interconnect structure 120. A second exposed bond pad 132 of the first plurality of exposed bond pads 116 is coupled to the first central bond pad 112 by a conductive path in the first interconnect structure 104. The combination of features described herein form a first bonding test structure 121.

The first bonding test structure 121 may be used in conjunction with an electrical test to detect an offset of the second substrate 122 from the intended position of the second substrate 122. When the second substrate 122 is bonded to the first substrate 102, the position of the second substrate is chosen to align bond pads of the first bonding layer to bond pads of the second bonding layer, electrically coupling conductive paths of the first interconnect structure 104 to conductive paths of the second interconnect structure 120. After applying a test voltage to the first exposed bond pad 130, the voltage of the second exposed bond pad 132 is measured to determine if the first exposed bond pad 130 and the second exposed bond pad 132 are electrically coupled. Subsequently, a voltage at the first plurality of exposed bond pads 116 coupled to the first plurality of peripheral bond pads 114 is measured to determine if the first plurality of peripheral bond pads 114 are coupled to the first overlying bond pad 128. If the measured voltage is over a threshold (e.g., greater than 0.1 volt), then it is determined that one or more of the first plurality of peripheral bond pads 114 are coupled to the first overlying bond pad 128, and there is a significant amount of offset in the position of the second substrate 122 that will impact the functionality of the integrated circuit.

An electrical test to determine the offset of the second substrate 122 performed after bonding the second substrate 122 to the first substrate 102 is beneficial, as it does not rely on the surface quality and design of the alignment marks on the first and second substrate 102, 122 as optical inspection does, resulting in a faster and more accurate test. Further, resistances of the metal-to-metal bonds can be measured, resulting in increased information about the quality of the metal-to-metal bond being available. Additional embodiments described herein can indicate further information after the electrical test, such as the direction and amount of offset, or rotational offset of the second substrate.

As shown in the top view 100b of FIG. 1B, the first overlying bond pad 128 (shown in phantom) is directly over the first central bond pad 112. The first plurality of peripheral bond pads 114 surround the first central bond pad 112, and are spaced from the first central bond pad 112 by the first distance 118. In some embodiments, the first plurality of peripheral bond pads 114 comprise a first peripheral bond pad 138 spaced from the first central bond pad 112 in a first direction 140, a second peripheral bond pad 142 spaced from the first central bond pad 112 in a second direction 144 opposite the first direction 140, a third peripheral bond pad 146 spaced from the first central bond pad 112 in a third direction 148 perpendicular to the first direction 140, and a fourth peripheral bond pad 150 spaced from the first central bond pad 112 in a fourth direction 152 opposite the third direction 148.

In some embodiments, the first distance 118 is approximately between 0.4 and 1.5 micrometers, 0.8 and 2.5 micrometers, 0.5 and 2 micrometers, or within another similar range. When the second substrate (see 122 of FIG. 1A) is positioned such that the first overlying bond pad 128 overlies one or more bond pads of the first plurality of peripheral bond pads 114, the electrical test will show that the first exposed bond pad (see 130 of FIG. 1A) is electrically coupled to the one or more bond pads. The coupling of the first exposed bond pad (see 130 of FIG. 1A) to the one or more bond pads of the first plurality of peripheral bond pads 114 may be used to determine that the first overlying bond pad 128 is offset from the first central bond pad by the first distance 118 in the one or more directions corresponding to the one or more bond pads. For example, when the first exposed bond pad 130 is determined to be electrically coupled to the first peripheral bond pad 138 and the third peripheral bond pad 146, in some embodiments, it may be determined that the first overlying bond pad 128 is offset from the first central bond pad by the first distance 118 in the first direction 140 and the third direction 148.

As shown in the three dimensional view 100c of FIG. 1C, the first bonding layer 110 (shown in phantom) comprises the first central bond pad 112 and the first plurality of peripheral bond pads 114. The second bonding layer 126 comprises a first overlying bond pad 128 that directly overlies the first central bond pad 112. When the second substrate (see 122 of FIG. 1A) is bonded to the first substrate (see 102 of FIG. 1A) such that bond pads in the second bonding layer 126 are centered on corresponding bond pads of the first bonding layer 110, the first overlying bond pad 128 is centered on the first central bond pad 112, and no bond pads in the second bonding layer 126 directly overlie or are centered on the first plurality of peripheral bond pads 114.

In some embodiments, the bond pads (e.g., the first central bond pad 112, the first plurality of peripheral bond pads 114, and the first overlying bond pad 128) are rectangular are have lengths and widths between approximately 1 micrometers and 5 micrometers, between approximately 0.8 micrometers and 4.5 micrometers, between approximately 2 micrometers and 5.5 micrometers, or within another similar range. In other embodiments, the bond pads are circular and have a diameter between approximately 1 micrometers and 5 micrometers, between approximately 0.8 micrometers and 4.5 micrometers, between approximately 2 micrometers and 5.5 micrometers, or within another similar range. The lengths and widths of the bond pads are greater (e.g., over 20% greater) than the first distance 118 between the first central bond pad 112 and the first plurality of peripheral bond pads 114 so that the first overlying bond pad 128 may be coupled to the first central bond pad 112 and one or more peripheral bond pads of the first plurality of peripheral bond pads 114 at the same time.

If the lengths and widths of the bond pads were approximately equal to (e.g., less than 10% greater than the first distance 118) or less than the first distance 118, the first overlying bond pad 128 would either have a narrow window to or would not contact both the first central bond pad 112 and bond pads of the first plurality of peripheral bond pads 114. Further, an offset where the first overlying bond pad 128 contacts a peripheral bond pad would result in the first test bond pad (see 154 of FIG. 1A) not contacting the second test bond pad (see 156 of FIG. 1A), so the coupling would not be detectable at the other bond pads of the first plurality of exposed bond pads (see 116 of FIG. 1A). However, bond pads with lengths and widths greater than the provided ranges may make the bonding test structure less cost effective to use with smaller bonded dies, as the bonding test structure would use space on the die that would otherwise be used for coupling the circuit components of the integrated circuit.

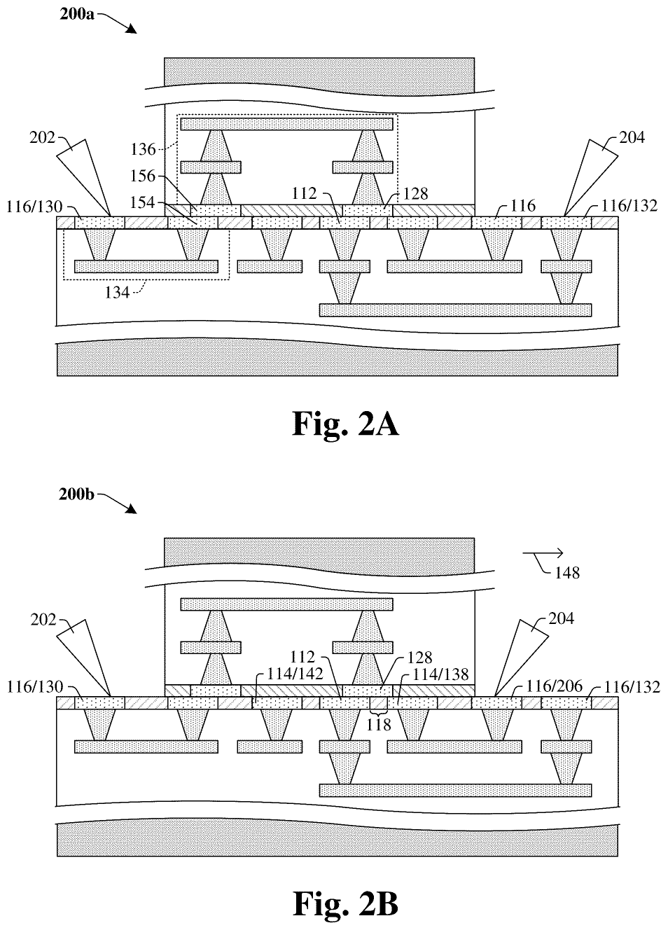

FIGS. 2A and 2B illustrate cross-sectional views 200a, 200b of some embodiments of a method of detecting an offset in the placement of the overlying substrate.

As shown in the cross-sectional view 200a of FIG. 2A, after the bonding test structure is formed (e.g., the first and second interconnect structures 104, 120 are formed over the first and second substrates 102, 122, the first and second bonding layers 110, 126 are formed on the first and second interconnect structure 104, 120 with the bond pads described in relation to FIGS. 1A-1C, and the first bonding layer 110 is bonded to the second bonding layer 126), an electrical test is performed on the integrated circuit. In some embodiments, the electrical test comprises applying a test voltage to the first exposed bond pad 130 using, for example, a first probe 202. In some embodiments, the test voltage is between 0.3 and 2 volts, between 0.5 and 3 volts, between 0.4 and 2.5 volts, or within another similar range. The electrical test is also called a bond shift test.

After the test voltage is applied to the first exposed bond pad 130, a voltage reading is taken at the second exposed bond pad 132 to determine if the first exposed bond pad 130 is electrically coupled to the second exposed bond pad (and, therefore, if the first overlying bond pad 128 is coupled to the first central bond pad 112). If there is an electrical short between the first exposed bond pad 130 and the second exposed bond pad 132, then the first overlying bond pad 128 is coupled to the first central bond pad 112, and a first test bond pad 154 and a second test bond pad 156 are electrically coupled. The first test bond pad 154 and the second test bond pad 156 couple the first conductive path 134 to the second conductive path 136, resulting in the electric coupling between the first exposed bond pad 130 and the first overlying bond pad 128. Without this electrical connection, the test is ended.

As shown in the cross-sectional view 200b of FIG. 2B, if there is an electrical short between the first exposed bond pad 130 and the second exposed bond pad 132, the test continues by measuring the voltage of the first plurality of exposed bond pads 116 that are coupled to the first plurality of peripheral bond pads 114. If one the other first plurality of exposed bond pads 116 is electrically shorted to the first exposed bond pad 130 (e.g., if the test voltage is measured at the bond pad), then the first overlying bond pad 128 is offset from being centered on the first central bond pad 112 by at least the first distance 118 in one or more directions. For example, as shown in the cross-sectional view 200b, the first overlying bond pad 128 directly overlies the first peripheral bond pad 138, forming an electrical coupling between the measured bond pad 206 and the first exposed bond pad 130. This indicates that the first overlying bond pad 128 is offset from being centered on the first central bond pad 112 by at least the first distance 118 in the first direction 140.

FIGD. 3A-3D illustrate top views 300a, 300b, 300c, 300d of one or more bonding test structures for determining the degree of offset in the placement of the overlying substrate and a rotation in the placement of the overlying substrate.

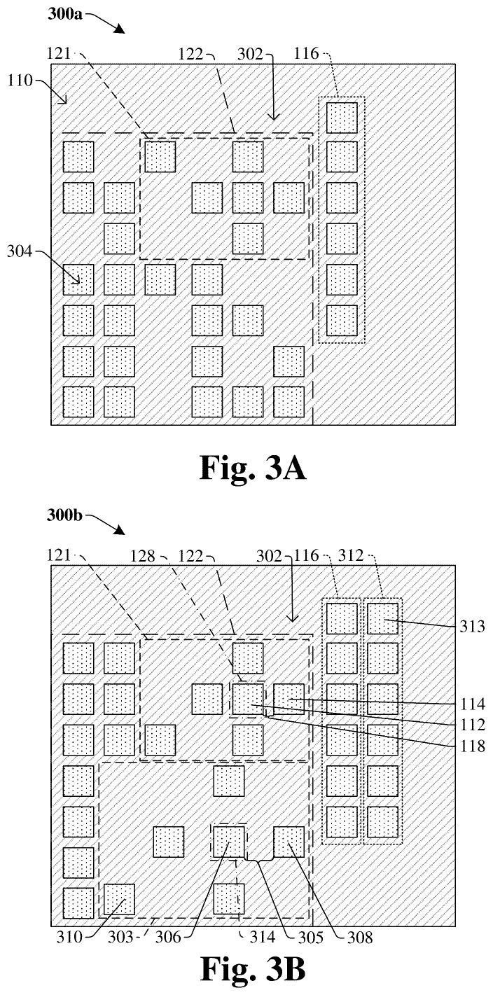

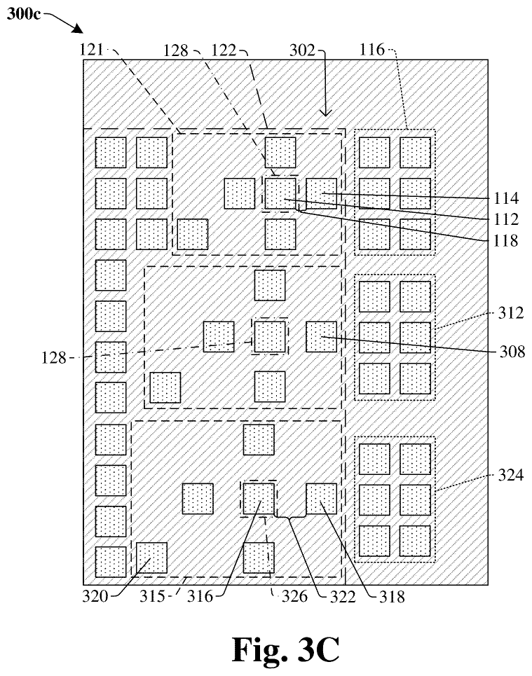

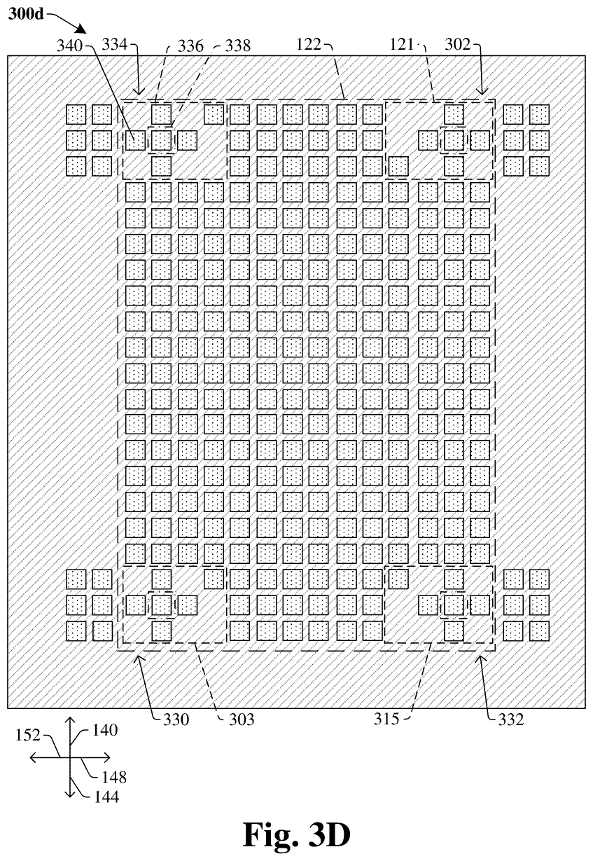

As shown in the top view 300a of FIG. 3A, in some embodiments, the first bonding test structure 121 is positioned at a first corner 302 (e.g., closer to the first corner than a second, third, or fourth corner) of the overlying substrate 122 (shown in phantom). The first plurality of exposed bond pads 116 are positioned past an outer sidewall of the overlying substrate 122. Additional bond pads 304 are part of an integrated circuit and are positioned in the first bonding layer 110 to bond to bond pads in the second bonding layer (see 126 of FIG. 1A). A misalignment of the second substrate 122 results in the additional bond pads 304 forming poor connections to the bond pads in the second bonding layer (see 126 of FIG. 1A) or potentially bonding to different bond pads than desired, resulting in unintended connections within the integrated circuit failure of the device. The addition of the first bonding test structure 121 to the integrated circuit and the performance of the electrical test determines if a misalignment has occurred and the direction the second substrate 122 is offset in.

As shown in the top view 300b of FIG. 3B, in some embodiments, a second bonding test structure 303 is positioned at the first corner 302 (e.g., closer to the first corner than a second, third, or fourth corner) of the overlying substrate 122 (shown in phantom). The second bonding test structure 303 comprises a second central bond pad 306, a second plurality of peripheral bond pads 308, and a second test bond pad 310. The second plurality of peripheral bond pads 308 surround the second central bond pad 306 and are a second distance 305 from the second central bond pad 306. The second distance 305 is greater than the first distance 118. In some embodiments, the second distance 305 is approximately (e.g., within 10% of) double the first distance 118. For example, in some embodiments, the first distance is approximately 0.5 micrometers, and the second distance is approximately 1 micrometer. The second plurality of peripheral bond pads 308, the second central bond pad 306, and the second test bond pad 310 are further coupled to a second plurality of exposed bond pads 312 by conductive paths within the first interconnect structure (see 104 of FIG. 1A), including a first exposed bond pad 313 of the second plurality of exposed bond pads 312. The second plurality of exposed bond pads 312 extend past outer sidewalls of the overlying substrate 122. The second test bond pad 310 is electrically coupled to the second central bond pad 306 by a conductive path in the second interconnect structure (see 120 of FIG. 1A) and a second overlying bond pad 314. In some embodiments, the first exposed bond pad 313 of the second plurality of exposed bond pads 312 is electrically coupled to the second overlying bond pad 314 through a conductive path extending through both the first interconnect structure (see 104 of FIG. 1A) and the second interconnect structure (see 120 of FIG. 1A).

In some embodiments, misalignment of the second substrate 122 (shown in phantom) results in the first overlying bond pad 128 being offset from being centered on the first central bond pad 112 and the second overlying bond pad 314 being offset from being centered on the second central bond pad 306. In further embodiments, the first overlying bond pad 128 is directly over and electrically coupled to a bond pad of the first plurality of peripheral bond pads 114, while the second overlying bond pad 314 is not directly over a bond pad of the second plurality of peripheral bond pads 308. As the first plurality of peripheral bond pads 114 are a first distance 118 away from the first central bond pad 112 and the second plurality of peripheral bond pads 308 are a second distance 305 from the second central bond pad 306, the resulting electrical connections may be used to determine that the overlying substrate 122 is offset by a distance greater than the first distance 118 but less than the second distance 305 in the direction of the electrically coupled bond pads. In this way, the amount of offset in the position of the overlying substrate 122 can be determined, leading to a faster and more accurate testing of pick and place offset and direction than optical testing provides.

As shown in the top view 300c of FIG. 3C, in some embodiments, a third bonding test structure 315 is positioned at the first corner 302 (e.g., closer to the first corner than a second, third, or fourth corner) of the overlying substrate 122 (shown in phantom). The third bonding test structure 315 comprises a third central bond pad 316, a third plurality of peripheral bond pads 318, and a third test bond pad 320. The third plurality of peripheral bond pads 318 surround the third central bond pad 316 and are a third distance 322 from the third central bond pad 316. The third distance 322 is greater than the first distance 118 and the second distance 305. The third plurality of peripheral bond pads 318, the third central bond pad 316, and the third test bond pad 320 are further coupled to a third plurality of exposed bond pads 324 by conductive paths within the first interconnect structure (see 104 of FIG. 1A). The third test bond pad 320 is electrically coupled to the third central bond pad 316 by a conductive path in the second interconnect structure (see 120 of FIG. 1A) and a third overlying bond pad 326.

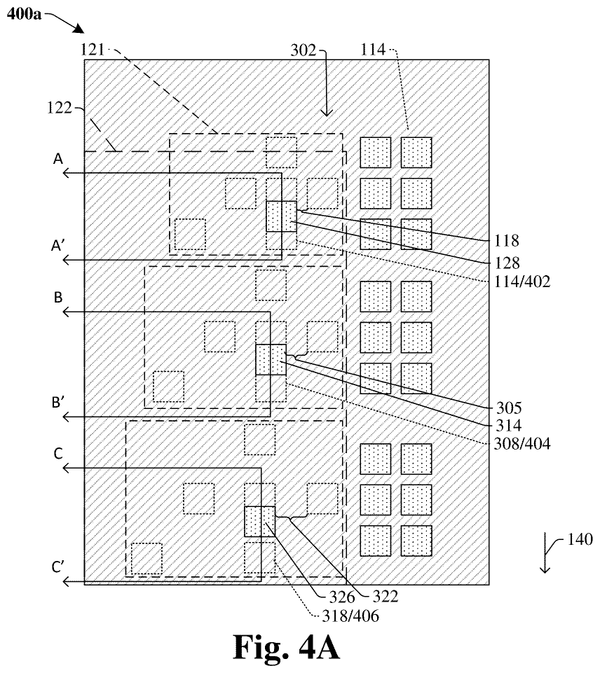

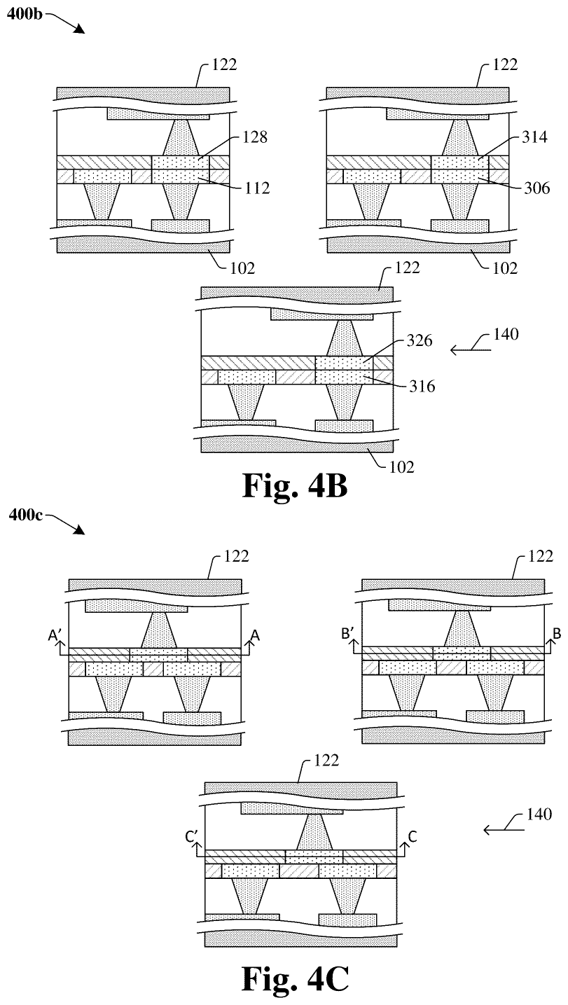

The additional of the third bonding test structure 315 results in an increased range of measured distances for the electrical test. A higher amount of bonding test structures results in a greater range of offset values available for the electrical test to measure. Another example with the first, second and third bonding test structure 121, 303, 315 is shown in FIGS. 4A, 4B, and 4C.

As shown in the top view 300d of FIG. 3D, in some embodiments, the first bonding test structure 121 is positioned at the first corner 302 (e.g., closer to the first corner 302 than a second corner 330, a third corner 332, or a fourth corner 334) of the overlying substrate 122 (shown in phantom). The second bonding test structure 303 is positioned at the second corner 330 of the overlying substrate 122 (shown in phantom) that is opposite the first corner 302. The third bonding test structure 315 is positioned at the third corner 332 of the overlying substrate 122 (shown in phantom). A fourth bonding test structure 336 is positioned at the fourth corner 334 of the overlying substrate 122 (shown in phantom). The fourth bonding structure 336 has a fourth distance (not shown) between a fourth central bond pad 338 and a fourth plurality of peripheral bond pads 340. In further embodiments, the fourth distance, the third distance (see 322 of FIG. 3C), and the second distance (see 305 of FIG. 3C), are substantially equal to the first distance (see 118 of FIG. 3C).

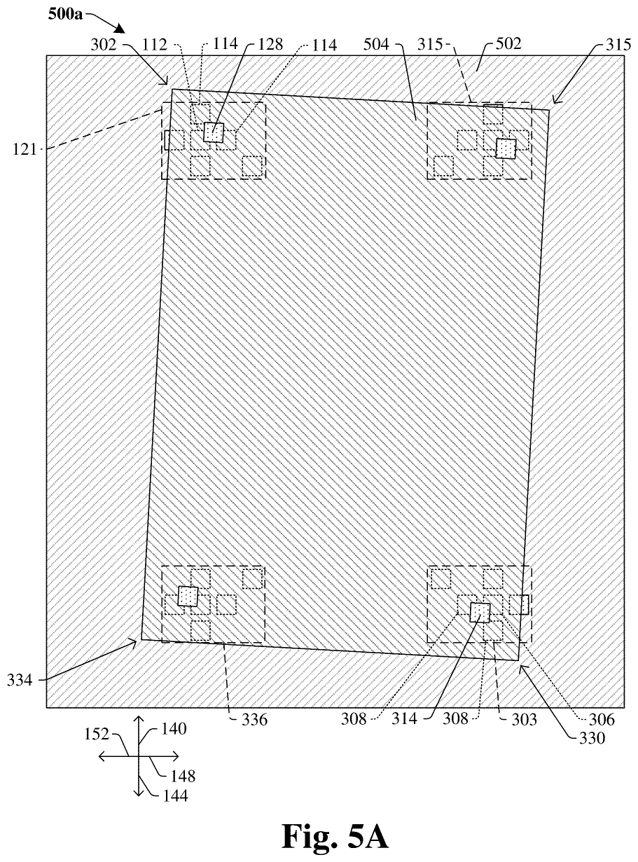

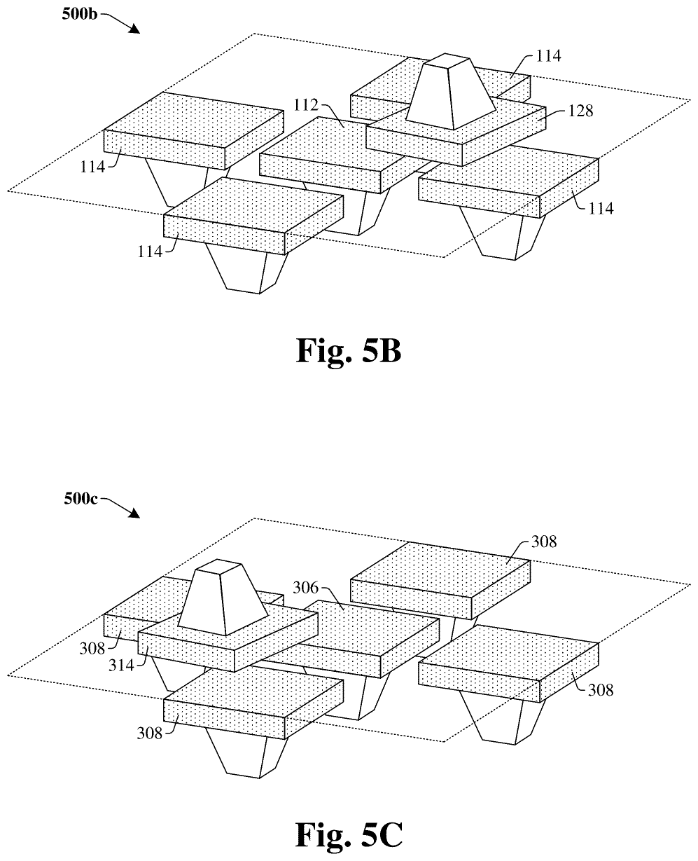

Embodiments with multiple (e.g., 2 or more) bonding test structures at different corners of the overlying substrate 122 (shown in phantom) result in a direction of rotation being determinable using an electrical test. Use of additional bonding test structures (e.g., the third bonding test structure 315 in the third corner 332 and the fourth bonding test structure 336 in the fourth corner 334) add additional readings and information to the test results. The additional information is used to make a more accurate determination of the amount of translational and rotational offset present in the overlying substrate 122. An example of an integrated circuit having a rotated overlying substrate 122 is shown in greater detail in FIGS. 5A, 5B, and 5C.

FIGS. 4A, 4B, and 4C illustrate a top view 400a and cross-sectional views 400b, 400c comparing some embodiments of an overlying substrate with no offset in the placement of the overlying substrate and an overlying substrate with a detectable offset in the placement of the overlying substrate. The cross-sectional views 400c of FIG. 4C are taken across lines A-A′, B-B′, and C-C′ of the top view 400a of FIG. 4A.

As shown in the top view 400a of FIG. 4A, in some embodiments the overlying substrate 122 (shown in phantom) is offset such that the first overlying bond pad 128 contacts a first bond pad 402 of the first plurality of peripheral bond pads 114, the second overlying bond pad 314 contacts a first bond pad 404 of the second plurality of peripheral bond pads 308, but the third overlying bond pad 326 does not contact a first bond pad 406 of the third plurality of peripheral bond pads 318. In this embodiments, the electrical test may determine that the overlying substrate 122 (shown in phantom) is offset in the direction of the electrically coupled bond pads (e.g., the first direction 140) by more than the second distance 305 and less than the third distance 322. In other embodiments, additional bonding test structures are formed at the first corner of the overlying substrate 122 (shown in phantom) where the additional bonding test structures have central bond pads and peripheral bond pads that are different distances apart (e.g., a fourth distance greater than the third distance, a fifth distance greater than the fourth distance, etc.). A higher amount of bonding test structures results in a greater range of offset values available for the electrical test to measure.

As shown in the cross-sectional view 400b of FIG. 4B, when the overlying substrate 122 is aligned with the first substrate 102, the first overlying bond pad 128 is centered on the first central bond pad 112, the second overlying bond pad 314 is centered on the second central bond pad 306, and the third overlying bond pad 326 is centered on the third central bond pad 316. As shown in the cross-sectional view 400c of FIG. 4C, when the overlying substrate 122 is misaligned with the first substrate 102 and offset in the first direction, the first overlying bond pad 128 is offset in the first direction from the first central bond pad 112 and contacts the first bond pad 402 of the first plurality of peripheral bond pads 114. Further, the second overlying bond pad 314 is offset in the first direction 140 from the second central bond pad 306 and contacts the first bond pad 404 of the second plurality of peripheral bond pads 308, and the third overlying bond pad 326 is offset in the first direction 140 from the third central bond pad 316 and contacts the first bond pad 406 of the third plurality of peripheral bond pads 318.

FIGS. 5A, 5B, and 5C illustrate a top view 500a and three dimensional views 500b, 500c of some embodiments of an overlying substrate with a detectable degree of rotation, a first bonding test structure 121 at a first corner 302 of the overlying substrate 122, and a second bonding test structure 303 at a second corner 330 of the overlying substrate. Additional bond pads, test bond pads, and the first and second plurality of exposed bond pads 116, 312 have been omitted for clarity. The three dimensional view 500b of FIG. 5B depicts the bond pads and coupled contacts in the first bonding test structure 121 of FIG. 5A. The three dimensional view 500c of FIG. 5C depicts the bond pads and coupled contacts in the second bonding test structure 303 of FIG. 5A.

As shown in the top view 500a of FIG. 5A, in some embodiments, the overlying substrate 122 is rotated in a clockwise direction, and the first overlying bond pad 128 is electrically coupled to the first central bond pad 112 and bond pads of the first plurality of peripheral bond pads 114 in the second direction 144 and the third direction 148. Further, the second overlying bond pad 314 at the second corner 330 is electrically coupled to the second central bond pad 306 and bond pads of the second plurality of peripheral bond pads 308 in the first direction 140 and the fourth direction 152. A first bond dielectric 502 of the first bonding layer 110 surrounds bond pads in the first bonding layer 110, and a second bond dielectric 504 of the second bonding layer 126 surround bond pads of the second bonding layer 126.

The electrical coupling between the first overlying bond pad 128 and the first plurality of peripheral bond pads 114 is determined during the electrical test, as well as the electrical coupling between the second overlying bond pad 314 and the second plurality of peripheral bond pads 308. By detecting the electrical couplings, the direction of shift of both the first overlying bond pad 128 and the second overlying bond pad 314 can be determined. As the direction of shift of the first overlying bond pad 128 appears to be in the first direction 140 and the third direction 148, and the direction of shift of the second overlying bond pad 314 appears to be in the second direction 144 and the fourth direction 152, the combined readings of the electrical test of the two bonding test structures is interpreted as a rotation of the overlying substrate 122 (shown in phantom). Use of additional bonding test structures (e.g., the third bonding test structure 315 in the third corner 332 and the fourth bonding test structure 336 in the fourth corner 334) at the four corners can add additional readings and information to the test results, resulting in a more accurate determination of the amount of translati onal and rotational offset present in the overlying substrate 122.

The three dimensional view 500b of FIG. 5B shows the structure of the first central bond pad 112, the first plurality of peripheral bond pads 114, and the first overlying bond pad 128 in greater detail. The three dimensional view 500c of FIG. 5C shows the structure of the second central bond pad 306, the second plurality of peripheral bond pads 308, and the second overlying bond pad 314 in greater detail.

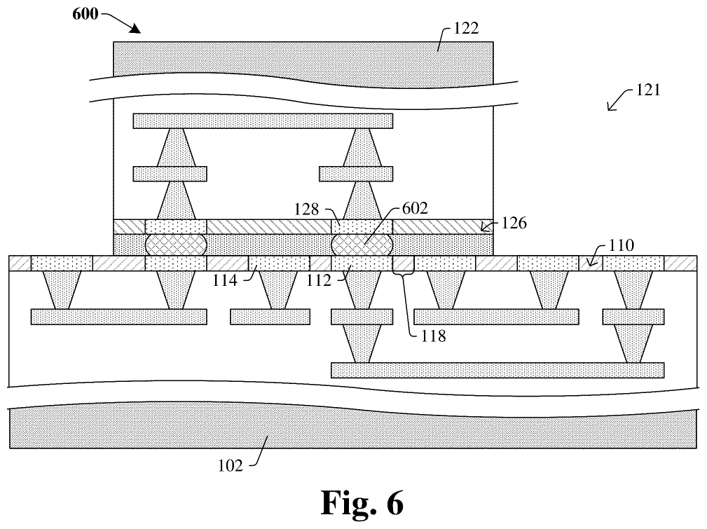

FIG. 6 illustrates a cross-sectional view 600 a bonding test structure where the overlying substrate is coupled to the underlying wafer using a plurality of micro-bumps.

In some embodiments, instead of using a dielectric-to-dielectric bond and a metal-to-metal bond to bond the first substrate 102 to the second substrate 122, a different bonding method is used. For example, in some embodiments, micro-bumps 602 are used to bond the first bonding layer 110 to the second bonding layer 126. The micro-bumps 602 are formed using a plating process on one of the first bonding layer 110 or the second bonding layer 126, and are used to form connections between the first bonding layer 110 or the second bonding layer 126. The micro-bumps 602 do not impede the electric tests performed using the first bonding test structure 121. In some embodiments utilizing micro-bumps, the size of the bond pads (e.g., the first central bond pad 112, the first plurality of peripheral bond pads 114, and the first overlying bond pad 128) are approximately between 10 micrometers and 30 micrometers, between 5micrometers and 20 micrometers, between 12 micrometers and 35 micrometers, or the like. In some embodiments utilizing micro-bumps, the first distance 118 is between 5 micrometers and 15 micrometers, between 3 micrometers and 10 micrometers, between 6 micrometers and 20 micrometers, or the like.

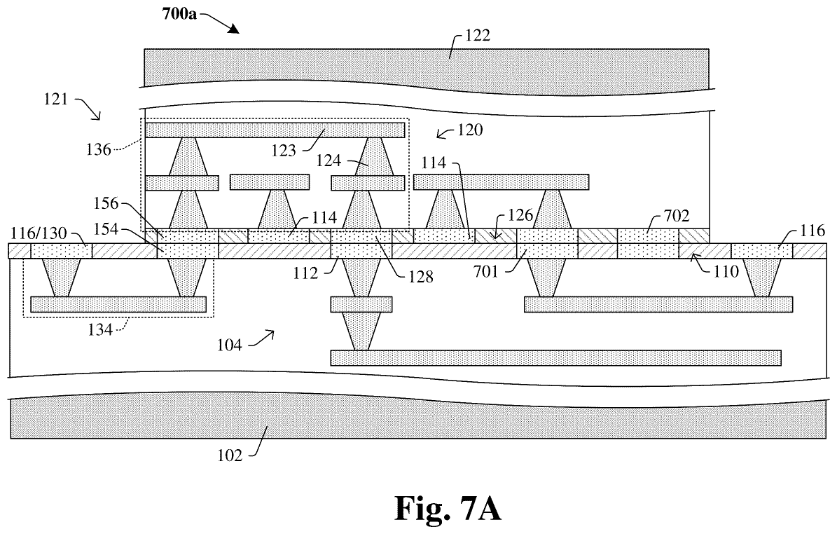

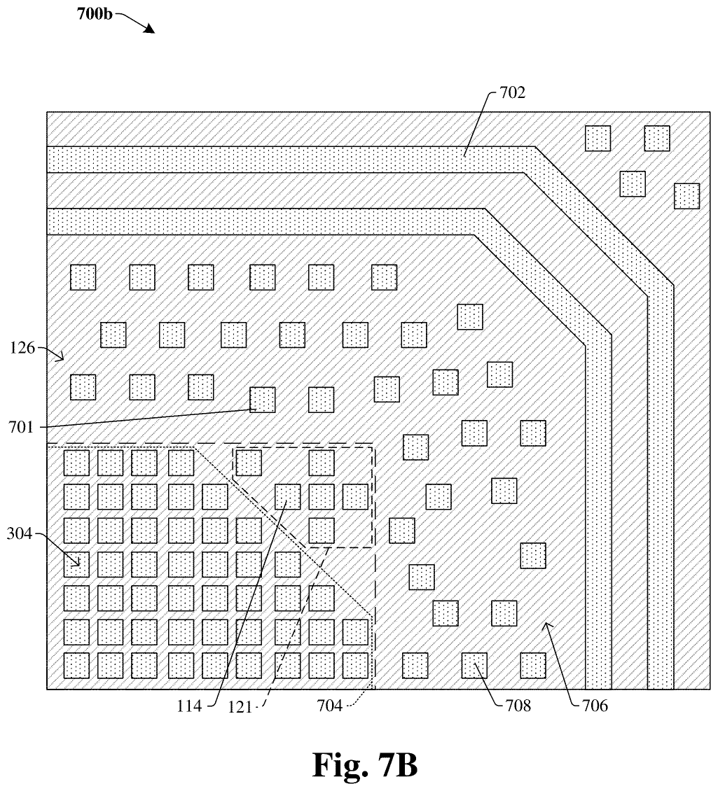

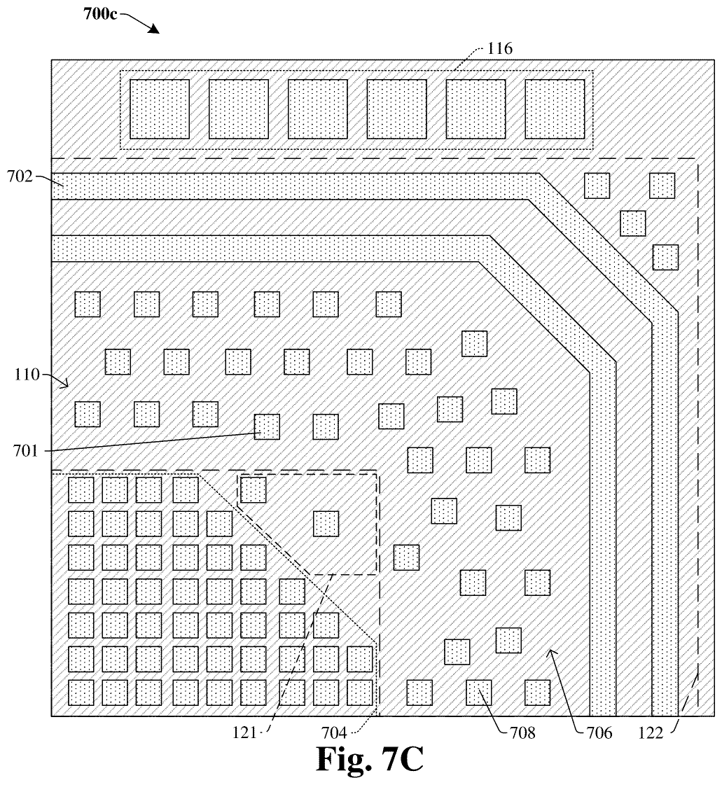

FIGS. 7A, 7B, and 7C illustrates a cross-sectional view 700a top views 700b, 700c of a device region surrounded by a seal ring where the test structure is positioned in a dummy metal region.

In some embodiments, as shown in FIG. 7A, the first plurality of peripheral bond pads 114 surround the first overlying bond pad 128 and are in the second bonding layer 126. The first plurality of peripheral bond pads 114 are coupled to outlying bond pads through the second interconnect structure 120. The outlying bond pads are coupled to the first plurality of exposed bond pads 116 through the first interconnect structure 104. A seal ring 702 extends between the bonding test structure 121 and outer sidewalls of the overlying substrate 122.

In some embodiments, as shown in FIG. 7B, the seal ring 702 surrounds the overlying substrate 122 (shown in phantom). The seal ring 702 is connected to a lid, protecting the integrated circuit on the first substrate (see 102 of FIG. 1A) and the overlying substrate 122 from damage. In the second bonding layer 126, the dummy metal region 706 extends between the seal ring 702 and a device region 704. The dummy metal region 706 comprises a plurality of dummy bond pads 708 distributed over the second bonding layer 126. In some embodiments, the device region 704 is surrounded by the dummy metal region 706. The device region 704 comprises the additional bond pads 304 that couple portions of the integrated circuit together. In some embodiments, the dummy metal region 706 of the second bonding layer 126 further comprises the first plurality of peripheral bond pads 114 as shown in FIG. 7A. In embodiments with the first plurality of peripheral bond pads 114 in the dummy metal region 706, the first bonding test structure 121 does not use space on the overlying substrate 122 (shown in phantom) that would otherwise be used for the integrated circuit (that is, the first bonding test structure 121 is not reducing the size of the device region 704). Therefore, the addition of the bonding test structures and the corresponding electrical tests in some embodiments result in a faster and less costly method of detecting a misalignment of the overlying substrate 122 without impinging on the area reserved for the integrated circuit formed within the first and second interconnect structures (see 104, 120 of FIG. 1A).

As shown in FIG. 7C, in some embodiments, the first plurality of exposed bond pads 116 are past the out sidewalls of the overlying substrate 122 and the seal ring 702. The first plurality of exposed bond pads 116 are coupled to the outlying bond pads 701 by wires extending beneath the seal ring 702. The outlying bond pads 701 are within the dummy metal region and are surrounded by dummy bond pads 708.

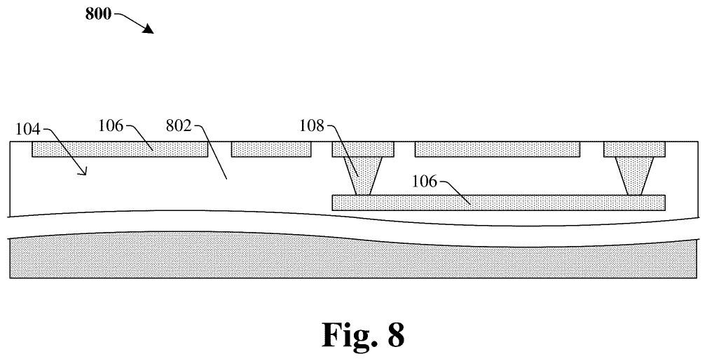

FIGS. 8-13 illustrate a series of cross-sectional views 800-1300 of some embodiments of a method of forming a DTI structure with complementary dipole generating layers. Although FIGS. 8-13 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 800 of FIG. 8, the first interconnect structure 104 is formed over the first substrate 102. The first interconnect structure comprises the first plurality of wire levels 106 and the first plurality of via levels 108 arranged to form conductive paths and surrounded by a first interlayer dielectric 802. In some embodiments, the first plurality of wire levels 106 and the first plurality of via levels 108 are or comprise a conductive material, such as copper, aluminum, tungsten, a conductive metal alloy, or the like. In some embodiments, the first interlayer dielectric 802 is or comprises an insulative material such as silicon dioxide (SiO₂), silicon nitride (Si₃N₄), or the like. In some embodiments, the first interconnect structure 104 is formed by repeatedly using one or more etching processes to etch openings for the via levels 108 and wire levels 106 within the first interlayer dielectric 802, and subsequently preforming a deposition process, such as PVD, ALD, or CVD, to deposit the conductive material into the openings. In some embodiments, the first interconnect structure 104 is formed using a plurality of damascene processes, a plurality of dual damascene processes, or the like.

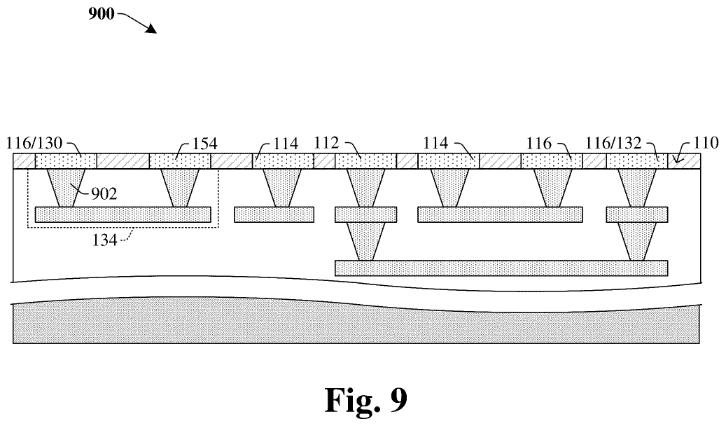

As shown in the cross-sectional view 900 of FIG. 9, the first bonding layer 110 and a first via level 902 is formed over the first interconnect structure 104. The first via level 902 comprises vias that couple bond pads of the first bonding layer 110 to the conductive paths of the first interconnect structure 104. The first bonding layer 110 comprises the first central bond pad 112, the first plurality of peripheral bond pads 114, the first plurality of exposed bond pads 116 (including the first exposed bond pad 130 and the second exposed bond pad 132), a first test bond pad 154, and the additional bond pads (see 304 of FIG. 3A). A first bond dielectric 502 surrounds the bond pads of the first bonding layer 110. In some embodiments, the bond pads and the vias of the first via level 902 are or comprise a conductive material, such as copper, aluminum, tungsten, a conductive metal alloy, or the like. In some embodiments, the first bond dielectric is or comprises an insulative material such as silicon dioxide (SiO₂), silicon nitride (Si₃N₄), or the like. In some embodiments, the first bonding layer 110 and the first via level 902 are formed by using one or more etching processes to etch openings for the vias and the bond pads, and subsequently preforming a deposition process, such as PVD, ALD, or CVD, to deposit the conductive material into the openings. In some embodiments, the first bonding layer 110 and the first via level 902 is formed using a plurality of damascene processes, a plurality of dual damascene processes, a plating process, or the like.

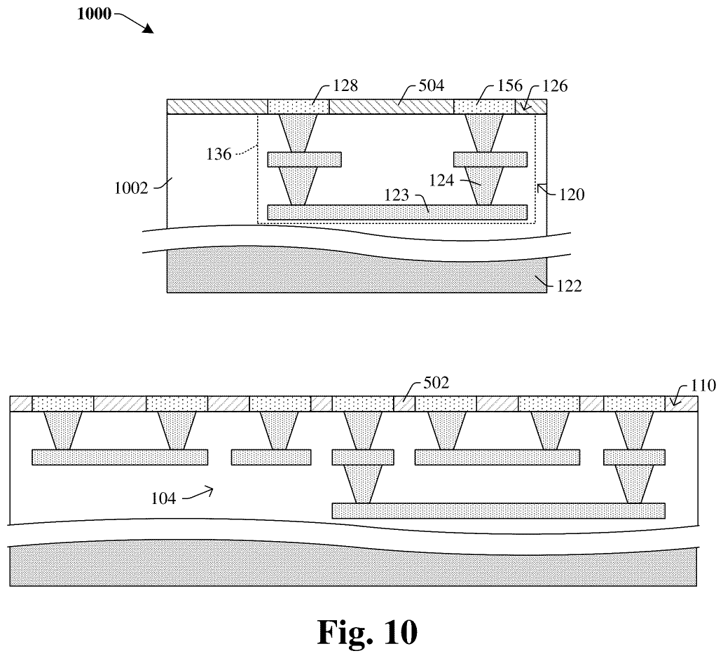

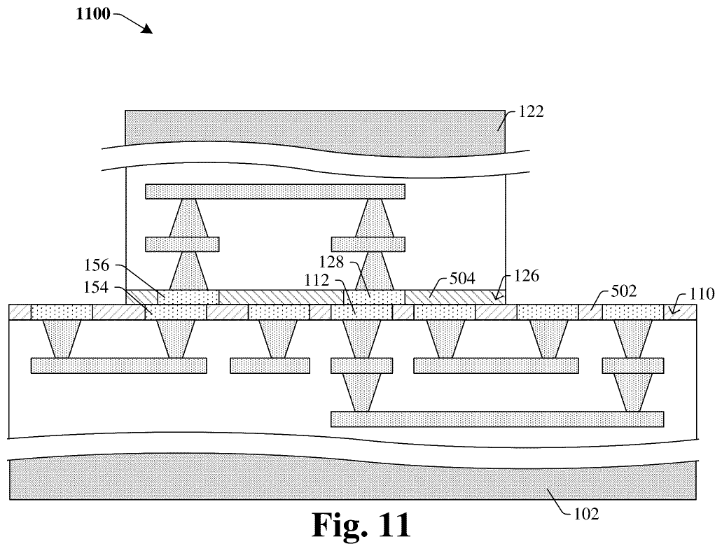

As shown in the cross-sectional view 1000 of FIG. 10, the second interconnect structure 120 and the second bonding layer 126 are formed on the second substrate 122. The second bonding layer 126 comprises the second test bond pad 156 and the first overlying bond pad 128. The second interconnect structure 120 comprises a second plurality of wire levels 123 and a second plurality of via levels 124 surrounded by a second interlayer dielectric 1002. The second plurality of wire levels 123 and the second plurality of via levels 124 form a second conductive path 136 in the second interconnect structure 120. In some embodiments, the second plurality of wire levels 123 and a second plurality of via levels 124 are or comprise a same material as the plurality of wire levels 106 and the plurality of via levels 108. In some embodiments, the second bonding layer 126 (e.g., the bond pads and the second bond dielectric 504) are or comprise the same materials as the bond pads of the first bonding layer 110 and the first bond dielectric 502, respectively. In some embodiments, the second interconnect structure 120 is formed in one of the ways described in relation to forming the first interconnect structure 104. In some embodiments, the second bonding layer 126 is formed in one of the ways described in relation to forming the first bonding layer 110.

As shown in the cross-sectional view 1100 of FIG. 11, the first bonding layer 110 is bonded to the second bonding layer 126. The second substrate 122 (and the second bonding layer 126) are positioned over the first substrate 102 (and the first bonding layer 110) using a pick-and-place process, where a pick-and-place machine is used to pick up the second substrate 122, align the second substrate 122 with its intended position on the first substrate 102, and placing the second substrate 122 onto the first substrate 102. As shown, in some embodiments, there is some offset in the alignment of the second substrate 122 with its intended position (e.g., where the bond pads of the second bonding layer 126 are centered on the corresponding bond pads of the first bonding layer 110).

After the second substrate 122 is positioned on the first substrate 102, the first bond dielectric 502 is bonded to the second bond dielectric 504 by applying pressure to the second substrate 122, pressing the second bond dielectric 504 into the first bond dielectric 502. An annealing process is subsequently performed, applying heat to the second substrate and bonding the bond pads of the first bonding layer 110 to the bond pads of the second bonding layer 126 while further reinforcing the dielectric-to-dielectric bond between the first bond dielectric 502 and the second bond dielectric 504. The combination of the dielectric-to-dielectric bond and the metal-to-metal bond is sometimes also known as a hybrid bond.

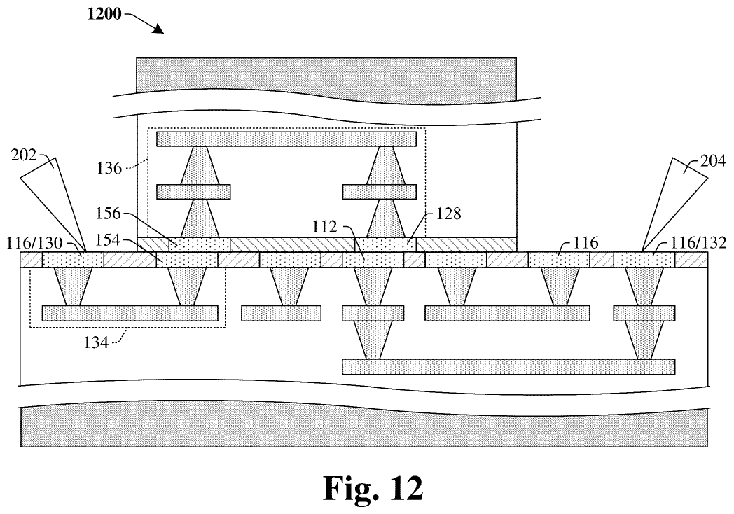

As shown in the cross-sectional view 1200 of FIG. 12, after the first bonding layer 110 is bonded to the second bonding layer 126, the electrical test is performed. In some embodiments, the electrical test comprises applying a test voltage to the first exposed bond pad 130 using, for example, a first probe 202. In some embodiments, the test voltage is between 0.3 and 2 volts, between 0.5 and 3 volts, between 0.4 and 2.5 volts, or within another similar range.

After the test voltage is applied to the first exposed bond pad 130, a voltage reading is taken at the second exposed bond pad 132 (using a second probe 204) to determine if the first exposed bond pad 130 is electrically coupled to the second exposed bond pad (and, therefore, if the first overlying bond pad 128 is coupled to the first central bond pad 112). If there is an electrical short between the first exposed bond pad 130 and the second exposed bond pad 132, then the first overlying bond pad 128 is coupled to the first central bond pad 112, and a first test bond pad 154 and a second test bond pad 156 are electrically coupled. The first test bond pad 154 and the second test bond pad 156 couple the first conductive path 134 to the second conductive path 136, resulting in the electric coupling between the first exposed bond pad 130 and the first overlying bond pad 128. Without this electrical connection, the device fails the electrical test, and it is determined that the overlying substrate 122 has an offset greater than the width of the bond pads.

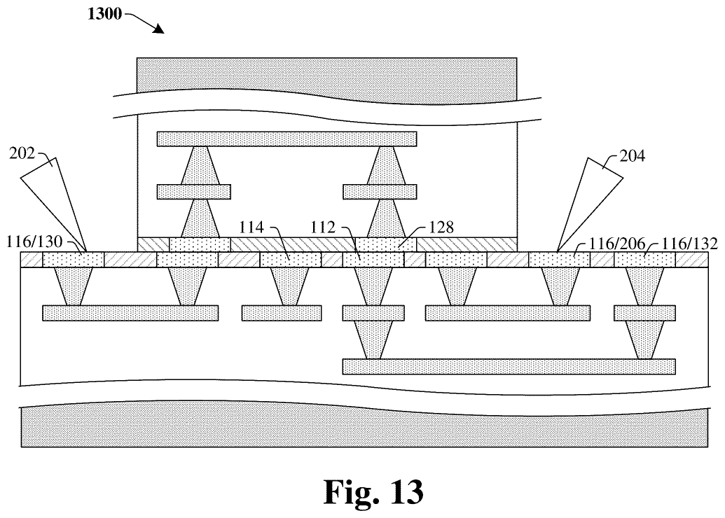

As shown in the cross-sectional view 1300 of FIG. 13, if there is an electrical short between the first exposed bond pad 130 and the second exposed bond pad 132, the test continues by measuring the voltage of the first plurality of exposed bond pads 116 that are coupled to the first plurality of peripheral bond pads 114. If at least one of the other first plurality of exposed bond pads 116 is electrically shorted to the first exposed bond pad 130 (e.g., if the test voltage or a voltage within 10% of the test voltage is measured at the bond pad), then the first overlying bond pad 128 is offset from being centered on the first central bond pad 112 by at least the first distance 118 in at least the direction of the bond pad measured, and the device fails the electrical test. If none of the exposed bond pads other than the second exposed bond pad 132 are electrically shorted to the first exposed bond pad 130, then the device passes the test, and the first overlying bond pad 128 is offset from being centered on the first central bond pad 112 by less than the first distance in every direction. For example, as shown in the cross-sectional view 1300, the first overlying bond pad 128 is not electrically coupled to the measured bond pad 206 or any other bond pads of the first plurality of peripheral bond pads 114. This indicates that the first overlying bond pad 128 is not sufficiently offset from being centered on the first central bond pad 112 to affect the operation of the integrated circuit in the device region (see 704 of FIG. 7). Therefore, the device passes the electrical test.

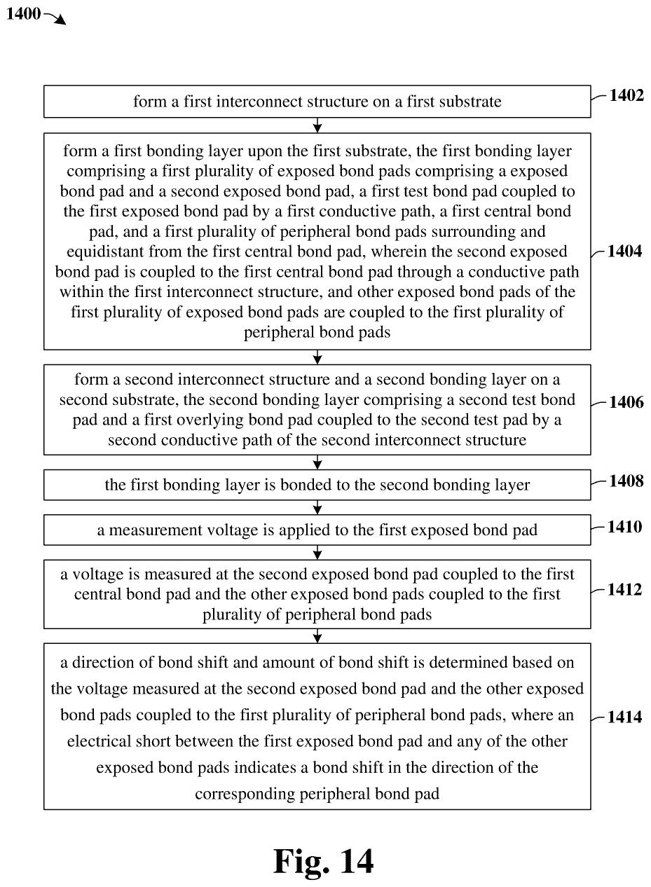

FIG. 14 illustrates a flowchart of some embodiments of a method of forming the bonding test structure and testing for an offset in the placement of the overlying substrate. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1402, a first interconnect structure is formed on a first substrate. An example of a drawing illustrating this step can be found, for example, in FIG. 8.

At 1404, a first bonding layer is formed upon the first substrate, the first bonding layer comprising a first plurality of exposed bond pads comprising a exposed bond pad and a second exposed bond pad, a first test bond pad coupled to the first exposed bond pad by a first conductive path, a first central bond pad, and a first plurality of peripheral bond pads surrounding and equidistant from the first central bond pad, wherein the second exposed bond pad is coupled to the first central bond pad through a conductive path within the first interconnect structure, and other exposed bond pads of the first plurality of exposed bond pads are coupled to the first plurality of peripheral bond pads. An example of a drawing illustrating this step can be found, for example, in FIG. 9.

At 1406, a second interconnect structure and a second bonding layer are formed on a second substrate, the second bonding layer comprising a second test bond pad and a first overlying bond pad coupled to the second test pad by a second conductive path of the second interconnect structure. An example of a drawing illustrating this step can be found, for example, in FIG. 10.

At 1408, the first bonding layer is bonded to the second bonding layer. An example of a drawing illustrating this step can be found, for example, in FIG. 11.

At 1410, a measurement voltage is applied to the first exposed bond pad. An example of a drawing illustrating this step can be found, for example, in FIG. 12.

At 1412, a voltage is measured at the second exposed bond pad coupled to the first central bond pad and the other exposed bond pads coupled to the first plurality of peripheral bond pads. An example of a drawing illustrating this step can be found, for example, in FIGS. 12-13.

At 1414, a direction of bond shift and amount of bond shift is determined based on the voltage measured at the second exposed bond pad and the other exposed bond pads coupled to the first plurality of peripheral bond pads, where an electrical short between the first exposed bond pad and any of the other exposed bond pads indicates a bond shift in the direction of the corresponding peripheral bond pad. An example of a drawing illustrating this step can be found, for example, in FIGS. 12-13.

Some embodiments relate to an integrated device, including: a first interconnect structure on a first substrate; a first central bond pad coupled to the first interconnect structure at a first bond interface; a first peripheral bond pad on a first side of the first central bond pad and separated from the first central bond pad by a first distance; a second peripheral bond pad on a second side of the first central bond pad and separated from the first central bond pad by a second distance substantially equal to the first distance, wherein the second side is opposite the first side; a second interconnect structure on a second substrate extending over the first central bond pad, the first peripheral bond pad, and the second peripheral bond pad; a first overlying bond pad coupled to the second interconnect structure and bonded to the first central bond pad at the first bond interface; and a plurality of exposed bond pads respectively coupled to the first central bond pad, the first peripheral bond pad, the second peripheral bond pad, and the first overlying bond pad, wherein the plurality of exposed bond pads extend past outer sidewalls of the second substrate.

Other embodiments relate to a photodetector array, including: a first interconnect structure on a first substrate; a second interconnect structure on a second substrate; a first bonding layer on the first interconnect structure, the first bonding layer including: a first central bond pad; a first plurality of peripheral bond pads positioned around the first central bond pad and separated from the first central bond pad by a first distance; a second central bond pad; a second plurality of peripheral bond pads positioned around the second central bond pad and separated from the second central bond pad by a second distance; and a plurality of exposed bond pads respectively coupled to the first central bond pad, the second central bond pad, the first plurality of peripheral bond pads, and the second plurality of peripheral bond pads; and a second bonding layer on the second interconnect structure, the second bonding layer including: a first overlying bond pad overlying the first central bond pad and coupled to a first exposed bond pad of the plurality of exposed bond pads by a conductive path extending through the first interconnect structure and the second interconnect structure; and a second overlying bond pad overlying the second central bond pad and coupled to a second exposed bond pad of the plurality of exposed bond pads by a conductive path extending through the first interconnect structure and the second interconnect structure.

Yet other embodiments relate to a method of detecting a bond shift, including: forming a first bonding test structure, wherein the first bonding test structure comprises a first central bond pad in a first bonding layer on a first interconnect structure, a first plurality of peripheral bond pads surrounding and equidistant from the first central bond pad, and a first overlying bond pad in a second bonding layer on a second interconnect structure; forming a first plurality of exposed bond pads respectively coupled to the first central bond pad, bond pads of the first plurality of peripheral bond pads, and the first overlying bond pad, wherein the first plurality of exposed bond pads are formed concurrently with forming the first central bond pad and the first plurality of peripheral bond pads; applying a measurement voltage to an exposed bond pad coupled to the first overlying bond pad; measuring a voltage at the first plurality of exposed bond pads coupled to the first central bond pad and the first plurality of peripheral bond pads; and determining a direction of bond shift based on the voltage measured at the first plurality of exposed bond pads coupled to the first plurality of peripheral bond pads.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising;
a first interconnect structure on a first substrate;
a first central bond pad coupled to the first interconnect structure at a first bond interface;
a first peripheral bond pad on a first side of the first central bond pad and separated from the first central bond pad by a first distance;
a second peripheral bond pad on a second side of the first central bond pad and separated from the first central bond pad by a second distance substantially equal to the first distance, wherein the second side is opposite the first side;
a second interconnect structure on a second substrate extending over the first central bond pad, the first peripheral bond pad, and the second peripheral bond pad;
a first overlying bond pad coupled to the second interconnect structure and bonded to the first central bond pad 112 at the first bond interface; and
a plurality of exposed bond pads respectively coupled to the first central bond pad, the first peripheral bond pad, the second peripheral bond pad, and the first overlying bond pad, wherein the plurality of exposed bond pads extend past outer sidewalls of the second substrate.

2. The integrated device of claim 1, further comprising:
a third peripheral bond pad on a third side of the first central bond pad and separated from the first central bond pad by a third distance substantially equal to the first distance; and
a fourth peripheral bond pad on a fourth side of the first central bond pad and separated from the first central bond pad by a fourth distance substantially equal to the first distance, wherein the fourth side is opposite the third side.

3. The integrated device of claim 1, further comprising:
a first exposed bond pad coupled to the first central bond pad by a first conductive path extending through the first interconnect structure and a second conductive path extending through the second interconnect structure; and
a second exposed bond pad coupled to the first central bond pad by a third conductive path extending through the first interconnect structure.

4. The integrated device of claim 1, wherein the first central bond pad is in a first bonding layer, the first overlying bond pad is in a second bonding layer, and the first and second peripheral bond pads are in one of the first bonding layer or the second bonding layer.

5. The integrated device of claim 4, further comprising:
a first bond dielectric on the first interconnect structure and spacing the first central bond pad from the first peripheral bond pad and the second peripheral bond pad; and
a second bond dielectric on the second interconnect structure and surrounding the first overlying bond pad, wherein the second bond dielectric is bonded to the first bond dielectric.

6. The integrated device of claim 4, wherein a center of the first overlying bond pad is offset from a center of the first central bond pad in a first direction, where the first direction is parallel to the first bond interface.

7. An integrated device, comprising:
a first interconnect structure on a first substrate;
a second interconnect structure on a second substrate;
a first bonding layer on the first interconnect structure, the first bonding layer comprising:
a first central bond pad;
a first plurality of peripheral bond pads positioned around the first central bond pad and separated from the first central bond pad by a first distance;
a second central bond pad;
a second plurality of peripheral bond pads positioned around the second central bond pad and separated from the second central bond pad by a second distance; and
a plurality of exposed bond pads respectively coupled to the first central bond pad, the second central bond pad, the first plurality of peripheral bond pads, and the second plurality of peripheral bond pads;
a second bonding layer on the second interconnect structure, the second bonding layer comprising:
a first overlying bond pad overlying the first central bond pad and coupled to a first exposed bond pad of the plurality of exposed bond pads by a conductive path extending through the first interconnect structure and the second interconnect structure; and
a second overlying bond pad overlying the second central bond pad and coupled to a second exposed bond pad of the plurality of exposed bond pads by a conductive path extending through the first interconnect structure and the second interconnect structure.

8. The integrated device of claim 7, wherein the second substrate comprises four corners, wherein the first central bond pad and the second central bond pad are closer to a first corner of the four corners than to a second, third, or fourth corner of the four corners.

9. The integrated device of claim 7, wherein the first distance is less than the second distance.

10. The integrated device of claim 7, wherein the second substrate comprises four corners, wherein the first central bond pad is closer to a first corner of the four corners than to a second, third, or fourth corner of the four corners, wherein the second central bond pad is closer to the second corner of the four corners than to the first, third, or fourth corner of the four corners.

11. The integrated device of claim 10, wherein the first distance is substantially equal to the second distance.

12. The integrated device of claim 7, wherein the second substrate comprises four corners, wherein the first central bond pad is closer to a first corner of the four corners than to a second, third, or fourth corner of the four corners, wherein the second central bond pad is closer to the second corner of the four corners than to the first, third, or fourth corner of the four corners;
wherein the first central bond pad is separated from the second central bond pad by a third distance;
wherein the first overlying bond pad is separated from the second overlying bond pad by a fourth distance that is substantially equal to the third distance;
wherein the first overlying bond pad is coupled to the first central bond pad; and
wherein the second overlying bond pad is coupled to the second central bond pad.

13. A method of detecting a bond shift, comprising:
forming a first bonding test structure, wherein the first bonding test structure comprises a first central bond pad in a first bonding layer on a first interconnect structure, a first plurality of peripheral bond pads surrounding and equidistant from the first central bond pad, and a first overlying bond pad in a second bonding layer on a second interconnect structure;
forming a first plurality of exposed bond pads respectively coupled to the first central bond pad, the first plurality of peripheral bond pads, and the first overlying bond pad, wherein the first plurality of exposed bond pads are formed concurrently with forming the first central bond pad and the first plurality of peripheral bond pads;
applying a measurement voltage to an exposed bond pad coupled to the first overlying bond pad;
measuring a voltage at the first plurality of exposed bond pads coupled to the first central bond pad and the first plurality of peripheral bond pads; and
determining a direction of bond shift based on the voltage measured at the first plurality of exposed bond pads coupled to the first plurality of peripheral bond pads.

14. The method of claim 13, wherein the first plurality of peripheral bond pads further comprise:
a first peripheral bond pad spaced from the first central bond pad in a first direction;
a second peripheral bond pad spaced from the first central bond pad in a second direction opposite the first direction;
a third peripheral bond pad spaced from the first central bond pad in a third direction perpendicular to the first direction; and
a fourth peripheral bond pad spaced from the first central bond pad in a fourth direction opposite the third direction;
wherein the direction of offset is determined to be in the direction of the peripheral bond pads of the first plurality of peripheral bond pads where the voltage is measured to be greater than 0.1 volt.

15. The method of claim 14, wherein when the voltage measured on the first peripheral bond pad is greater than 0.1 volt, the direction of the bond shift is determined to be in the first direction.

16. The method of claim 14, wherein when the voltage measured on the first peripheral bond pad is greater than 0.1 volt, and the voltage measured on the third peripheral bond pad is greater than 0.1 volt, the direction of the bond shift is determined to be in both the first direction and the third direction.

17. The method of claim 13, further comprising:
forming a second bonding test structure, wherein the second bonding test structure comprises a second central bond pad in the first bonding layer on the first interconnect structure, a second plurality of peripheral bond pads surrounding and equidistant from the second central bond pad, and a second overlying bond pad in the second bonding layer on the second interconnect structure;
forming a second plurality of exposed bond pads concurrently with forming the second central bond pad and the second plurality of peripheral bond pads, wherein the second plurality of exposed bond pads are electrically coupled to the second central bond pad and the second plurality of peripheral bond pads through conductive paths extending through the first interconnect structure, and wherein a bond pad of the second plurality of exposed bond pads is electrically coupled to the second overlying bond pad through a conductive path extending through the first interconnect structure and the second interconnect structure;
wherein the second interconnect structure is coupled to a substrate that has a first corner and a second corner opposite the first corner, wherein the first bonding test structure is closer to the first corner than the second corner, and wherein the second bonding test structure is closer to the second corner than the first corner;
applying the measurement voltage to an exposed bond pad coupled to the second overlying bond pad;
measuring the voltage at the second plurality of exposed bond pads coupled to the second central bond pad and the second plurality of peripheral bond pads; and
determining a direction of rotational offset based on the voltage measured at the first plurality of exposed bond pads coupled to the first plurality of peripheral bond pads and the voltage measured at the second plurality of exposed bond pads coupled to the second plurality of peripheral bond pads.

18. The method of claim 13, further comprising:
forming a second bonding test structure, wherein the second bonding test structure comprises a second central bond pad in the first bonding layer on the first interconnect structure, a second plurality of peripheral bond pads surrounding and equidistant from the second central bond pad, and a second overlying bond pad in the second bonding layer on the second interconnect structure, wherein the first plurality of peripheral bond pads are a first distance from the first central bond pad, and the second plurality of peripheral bond pads are a second distance from the second central bond pad, wherein the second distance is different from the first distance;
forming a second plurality of exposed bond pads concurrently with forming the second central bond pad and the second plurality of peripheral bond pads, wherein the second plurality of exposed bond pads are respectively coupled to the second central bond pad and bond pads of the second plurality of peripheral bond pads through conductive paths extending through the first interconnect structure, and wherein a bond pad of the second plurality of exposed bond pads is electrically coupled to the second overlying bond pad through a conductive path extending through the first interconnect structure and the second interconnect structure;
applying the measurement voltage to an exposed bond pad coupled to the second overlying bond pad;
measuring the voltage at the second plurality of exposed bond pads coupled to the second central bond pad and the second plurality of peripheral bond pads; and
determining an amount of offset based on the voltage measured at the first plurality of exposed bond pads coupled to the first plurality of peripheral bond pads, the second plurality of exposed bond pads coupled to the second plurality of peripheral bond pads, the first distance, and the second distance.

19. The method of claim 18, wherein the second interconnect structure is coupled to a substrate that has a first corner and a second corner opposite the first corner, wherein the first bonding test structure and the second bonding test structure are closer to the first corner than the second corner.

20. The method of claim 13, wherein forming the first bonding test structure and forming the first plurality of exposed bond pads further comprises:
forming the first interconnect structure on a first substrate, the first interconnect structure comprising a first plurality of conductive paths, further comprising a first conductive path;
forming the first bonding layer on the first substrate, the first bonding layer comprising the first plurality of exposed bond pads, the first central bond pad, the first plurality of peripheral bond pads, and a first bonding dielectric extending between the first plurality of exposed bond pads, the first central bond pad, and the first plurality of peripheral bond pads, wherein the first plurality of conductive paths respectively couple the first central bond pad and the first plurality of peripheral bond pads to the first plurality of exposed bond pads;
forming the second interconnect structure on a second substrate, the second interconnect structure comprising a second conductive path;
forming the second bonding layer on the first substrate, the second bonding layer comprising the first overlying bond pad, and a second bonding dielectric surrounding the first overlying bond pad; and
bonding the first bonding layer to the second bonding layer, resulting in a bonding of the first overlying bond pad to the first central bond pad, wherein the second conductive path couples the first overlying bond pad to a first exposed bond pad of the first plurality of exposed bond pads through the first conductive path.
